(19) United States
(12) Patent Application Publication
(10) Pub. No.: US 2011/0108314 A1
(43) Pub. Date: May 12, 2011

(54) ACTIVE DEVICE ARRAY SUBSTRATE

(76) Inventors: Horng-Wei PAN, Taipei City (TW); Te-Hsing Kuo, Taoyuan City (TW)

(21) Appl. No.: 12/703,280

(22) Filed: Feb. 10, 2010

(30) Foreign Application Priority Data
Nov. 10, 2009 (TW) 098220790

(51) Int. Cl. H05K 1/11

(52) U.S. Cl. 174/261

(57) ABSTRACT

An active device array substrate includes a substrate, a pixel array, a plurality of terminals, and a plurality of leads. The pixel array is disposed on the substrate and includes a plurality of intersecting signal lines arranged in a mesh shape. The terminals are disposed on the substrate. The leads are disposed on the substrate. Each lead includes a plurality of line segments connected in series, and each terminal is connected between one of the line segments and one of the signal lines. Two angles exist between the edge of one line segment and the edge of another line segment connected to the line segment, and the angles are not equal to 180°.

### CROSS-REFERENCE TO RELATED APPLICATION

This application claims the benefit of Taiwan Patent Application No. 098220790, filed on Nov. 11, 2009, which is hereby incorporated by reference for all purposes as if fully set forth herein.

### BACKGROUND OF THE INVENTION

1. Field of Invention

The present invention relates to a device array substrate, and more particularly to an active device array substrate applicable to a display panel.

2. Related Art

In the current liquid crystal display (LCD) manufacturing process, edges of a thin film transistor (TFT) array substrate are generally ground, such that the stress is not easily concentrated on the edges, thereby reducing the breakage probability of the TFT array substrate.

FIG. 1A is a schematic top view of a conventional TFT array substrate without ground. Referring to FIG. 1A, a conventional TFT array substrate 100 includes a substrate 110, a pixel array 120, a plurality of terminals 130, a plurality of leads 140, and a shorting ring 150.

The pixel array 120, the terminals 130, the leads 140, and the shorting ring 150 are all disposed on the substrate 110. The pixel array 120 includes a plurality of scan lines 122. The terminals 130 are connected to the scan lines 122, and the leads 140 are connected between the terminals 130 and the shorting ring 150. The shorting ring 150 can be electrically connected to all the scan lines 122 through the leads 140 and the terminals 130, such that the scan lines 122 are electrically conducted with one another and thus are in a short-circuit state.

FIG. 1B is a schematic cross-sectional view taken along Line I-I in FIG. 1A. Referring to FIGS. 1A and 1B, when the TFT array substrate 100 is not ground, an edge E1 of the substrate 110 is in an angular shape, as shown in FIG. 1B. At this time, the stress is easily concentrated on the edge E1, so that the breakage easily occurs at the edge E1.

FIG. 1C is a schematic top view of the TFT array substrate in FIG. 1A after ground. FIG. 1D is a schematic cross-sectional view taken along Line II-II in FIG. 1C. Referring to FIGS. 1C and 1D, in order to reduce the breakage probability of the edge E1, the TFT array substrate 100 in FIG. 1A is ground, so as to form a TFT array substrate 100′.

In detail, a worn surface F1 is formed at the edge E1′ of the substrate 110′ in the TFT array substrate 100′, and the worn surface F1 is a chamfer, as shown in FIG. 1D. Thus, the stress is not easily concentrated on the edge E1′, so as to reduce the breakage probability of the edge E1′ of the substrate 110′. In addition, after the TFT array substrate 100 is ground, the shoring ring 150 is removed, so as to release the scan lines 122 from the short-circuit state.

Furthermore, after grinding the TFT array substrate 100, the leads 140 are partially removed, so as to form a plurality of leads 140′, as shown in FIG. 1C. A length L1 of every lead 140′ is restricted within a quality control range. Once the length L1 exceeds the quality control range, it indicates that the quality of the TFT array substrate 100′ is unacceptable and cause that the TFT array substrate 100′ may have to be reworked or even discarded.

Generally speaking, the leads 140′ are usually examined under an optical microscope, so as to measure whether the length L1 of every lead 140′ falls within the quality control range, and determine whether the quality of the TFT array substrate 100′ is acceptable accordingly, thereby determining whether the TFT array substrate 100′ can be subjected to subsequent normal procedures, or has to be reworked or even discarded.

### SUMMARY OF THE INVENTION

Accordingly, the present invention is directed to an active device array substrate, in which at least one lead includes a plurality of line segments connected in series, and the line segments are distinguishable in vision.

The present invention provides an active device array substrate including a substrate, a pixel array, a plurality of terminals, and a plurality of leads. The pixel array is disposed on the substrate and includes a plurality of intersecting signal lines arranged in a mesh shape. The terminals are disposed on the substrate. The leads are disposed on the substrate. Each lead includes a plurality of line segments connected in series, and each terminal is connected between one of the line segments and one of the signal lines. Two angles exist between the edge of one line segment and the edge of another line segment connected to the line segment, and the angles are not equal to 180°.

Since the angles existing between the edge of one line segment and the edge of another line segment connected to the line segment are not equal to 180°, the line segments of the same lead can be distinguished in vision. Therefore, the present invention enables a worker to examine the active device array substrate conveniently, so as to accelerate the examination operation and reduce the time consumed by the examination operation.

In order to make the aforementioned and other objectives and advantages of the present invention comprehensible, embodiments accompanied with figures are described in detail below.

### BRIEF DESCRIPTION OF THE DRAWINGS

FIG. 1A is a schematic top view of a conventional TFT array substrate without ground;

FIG. 1B is a schematic cross-sectional view taken along Line I-I in FIG. 1A;

FIG. 1C is a schematic top view of the TFT array substrate in FIG. 1A after ground;

FIG. 1D is a schematic cross-sectional view taken along Line II-II in FIG. 1C;

FIG. 2A is a schematic top view of an active device array substrate according to a first embodiment of the present invention;

FIG. 2B is a partially enlarged schematic view of a lead in FIG. 2A;

FIG. 3A is a schematic top view of an active device array substrate according to a second embodiment of the present invention;

FIG. 3B is a partially enlarged schematic view of a lead in FIG. 3A;

FIG. 4A is a schematic top view of an active device array substrate according to a third embodiment of the present invention; and

FIG. 4B is a partially enlarged schematic view of a lead in FIG. 4A.

### DETAILED DESCRIPTION OF THE INVENTION

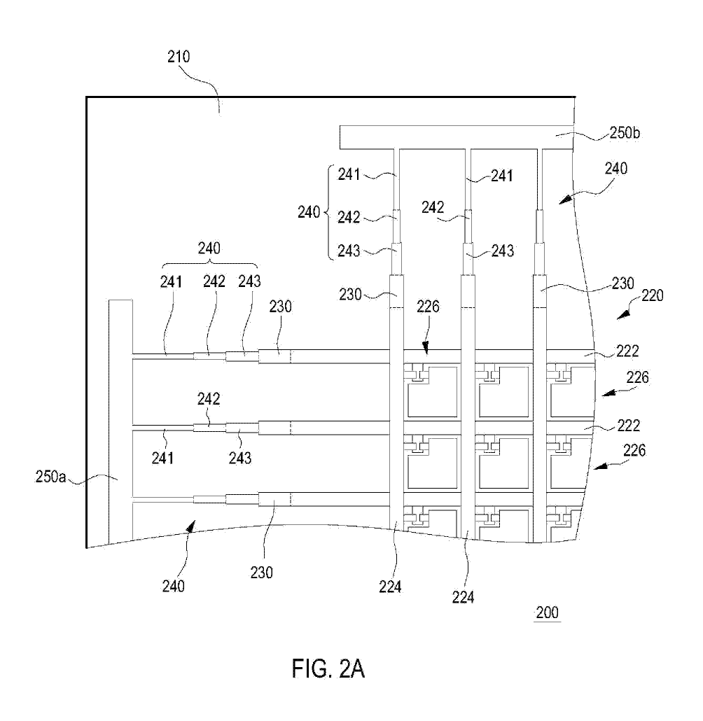

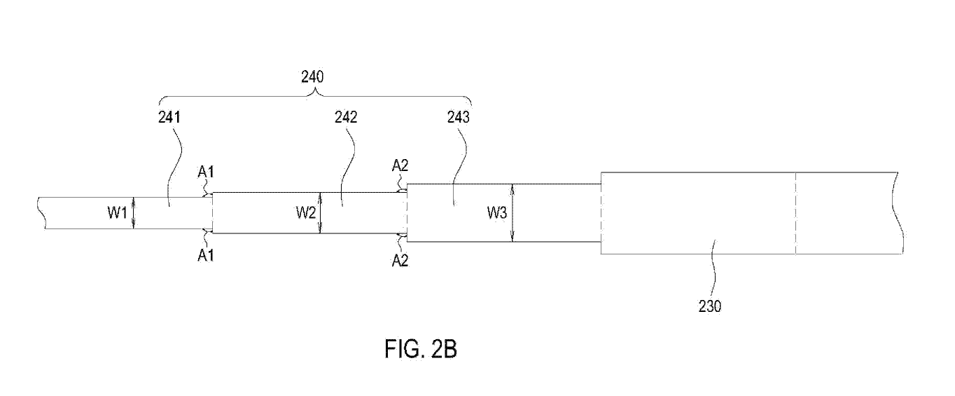

FIG. 2A is a schematic top view of an active device array substrate according to a first embodiment of the present invention. Referring to FIG. 2A, an active device array substrate 200 in this embodiment includes a substrate 210, a pixel array 220, a plurality of terminals 230, and a plurality of leads 240. The pixel array 220, the terminals 230, and the leads 240 are all disposed on the substrate 210. In addition, the active device array substrate 200 shown in FIG. 2A has not been ground yet, so that the active device array substrate 200 further includes two shorting rings 250a and 250b connecting the leads 240.

The pixel array 220 includes a plurality of intersecting signal lines 222, 224 arranged in a mesh shape. The signal lines 222 are scan lines, and the signal lines 224 are data lines. In this embodiment, all the signal lines 222, 224 are connected to the terminals 230. Each of the signal lines 222 (that is, scan line) is connected to one terminal 230, and each of the signal lines 224 (that is, data line) is connected to another terminal 230.

The pixel array 220 may further include a plurality of pixel units 226. The pixel units 226 are electrically connected to the signal lines 222, 224 and able to control the rotation of liquid crystal molecules, so as to enable an LCD to display images. The pixel units 226 may have the same structure as pixel units in a present LCD, that is, the technical features of the structure of the pixel units 226 may be known in the prior art, so that the pixel units 226 will not be introduced herein.

The terminals 230 are not only connected to the signal lines 222, 224, but also connected to the leads 240. In detail, among the terminals 230 connected to the signal lines 222, each terminal 230 is connected between one of the leads 240 and one of the signal lines 222. Among the terminals 230 connected to the signal lines 224, each terminal 230 is connected between another lead 240 and one of the signal lines 224.

In this embodiment, each signal line 222 may be integrated with the terminal 230 connected thereto to form a unity. Each signal line 224 may be integrated with the terminal 230 connected thereto to form a unity. In addition, an edge of each signal line 222 and an edge of the terminal 230 connected thereto may be aligned with each other, and an edge of each signal line 224 and an edge of the terminal 230 connected thereto may also be aligned with each other, as shown in FIG. 2A.

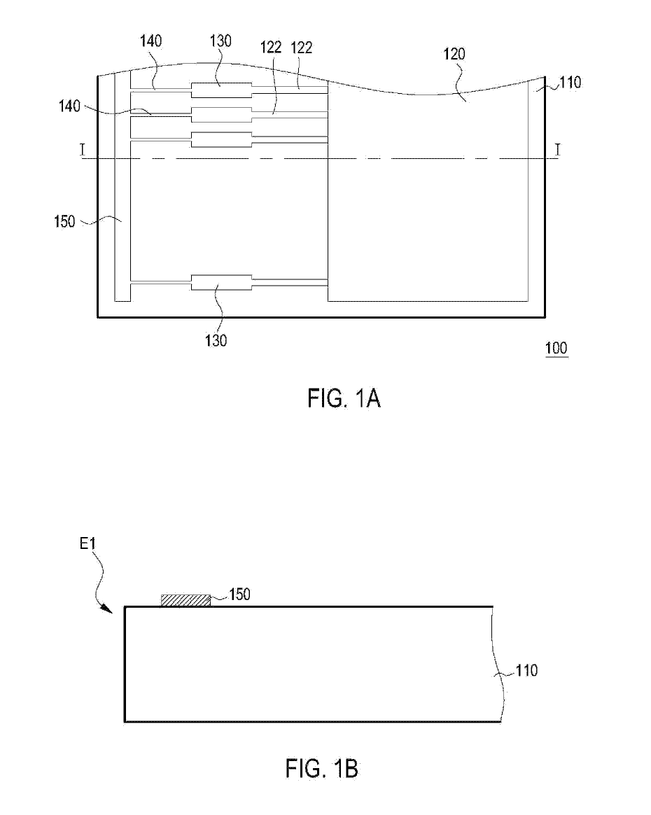

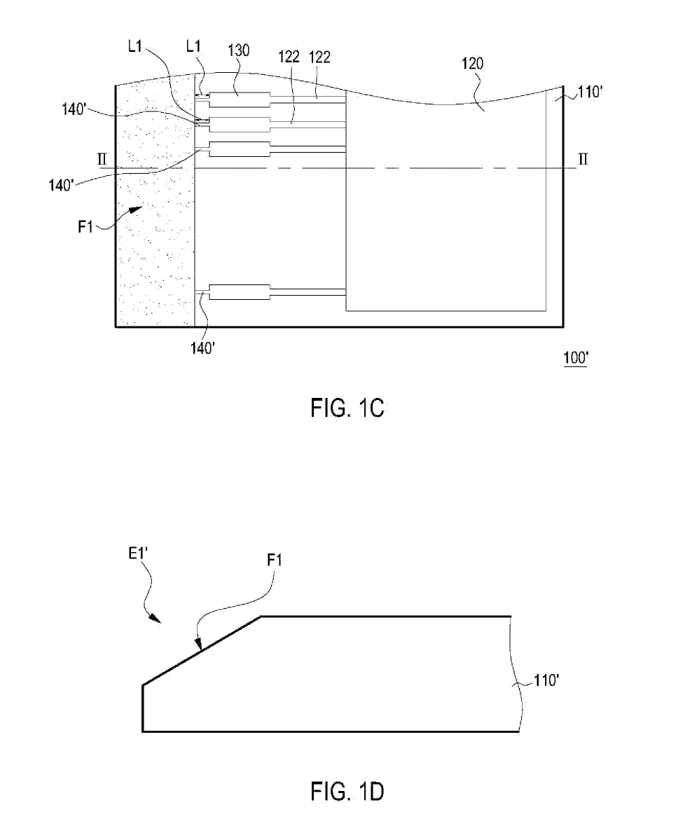

Definitely, in other embodiments not shown, as for the terminals 230 and the signal lines 222 connected to each other, edges of the terminals 230 may protrude from edges of the signal lines 222 (the TFT array substrates 100 and 100′ as shown in FIG. 1A). Likewise, as for the terminals 230 and the signal lines 224 connected to each other, edges of the terminals 230 may protrude from edges of the signal lines 224. Therefore, the shapes of the terminals 230 in FIG. 2A are merely illustrated as an example, but not intended to limit the present invention.

It should be noted that, although all the terminals 230 shown in FIG. 2A are connected to the signal lines 222, 224, each terminal 230 may only be connected to a signal line 222 or a signal line 224 in other embodiments not shown, that is, each terminal 230 is only connected to a scan line or a data line in the pixel array 220. For example, the terminals 230 are only connected to the signal lines 222 (that is, scan lines) but not connected to any signal lines 224 (that is, data lines), or the terminals 230 are only connected to the signal lines 224 (that is, data lines) but not connected to any signal lines 222 (that is, scan lines).

Each lead 240 includes a plurality of line segments 241, 242, and 243. The line segments 241, 242, 243 of the same lead 240 are connected in series. That is to say, in each of leads 240, the line segments 241, 242, 243 are connected with one another to form a string, and the line segment 242 is located between the line segment 241 and the line segment 243.

Since each lead 240 in FIG. 2A includes three line segments, namely, the line segments 241, 242, and 243, the number of line segments included by each lead 240 is more than two. However, in other embodiments not shown, the number of line segments included by each lead 240 may be only two. Therefore, the number of line segments included by each lead 240 in FIG. 2A is merely illustrated as an example, but not intended to limit the present invention.

The line segments 243 are respectively connected to the terminals 230. In detail, as for the terminals 230 connected to the signal lines 222, each terminal 230 is connected between one of the line segments 243 and one of the signal lines 222. As for the terminals 230 connected to the signal lines 224, each terminal 230 is connected between another line segment 243 and one of the signal lines 224.

FIG. 2B is a partially enlarged schematic view of a lead in FIG. 2A. Referring to FIGS. 2A and 2B, since the line segments 241, 242, and 243 of the same lead 240 are connected in series, in the same lead 240, an edge of the line segment 241 is connected to an edge of the line segment 242, and an edge of the line segment 242 is connected to an edge of the line segment 243.

According to the above, two angles A1 exist between the edge of the line segment 241 and the edge of the line segment 242 connected to the line segment 241, and two angles A2 exist between the edge of the line segment 242 and the edge of the line segment 243 connected to the line segment 242. The angles A1, A2 are not equal to 180°. In other words, the edges of the line segments 241, 242, and 243 are not aligned with one another, such that the line segments 241, 242, and 243 of the same lead 240 can be distinguished in vision.

In this embodiment, the line segments 241, 242, and 243 are substantially rectangular, and the angles A1, A2 are substantially equal to 90°. That is to say, a partial edge of the line segment 241 is substantially perpendicular to a partial edge of the line segment 242 connected to the line segment 241, and a partial edge of the line segment 242 is substantially perpendicular to a partial edge of the line segment 243 connected to the line segment 242.

In the same lead 240, a width W3 of the line segment 243 adjacent to the terminal 230 is greater than a width W2 of the line segment 242 and a width W1 of the line segment 241, and the width W2 is greater than the width W1. It can be seen that, as for two line segments connected to each other, for example, line segments 241 and 242, or line segments 242 and 243, the width of one line segment far away from the terminal 230 is smaller than the width of the other line segment. In addition, in the same lead 240, two line segments have different areas. For example, as seen from FIG. 2B, the line segments 241, 242, and 243 have different areas.

After grinding the active device array substrate 200, a worker can directly examine the appearance of the leads 240 after ground by using a common magnifying glass or optical microscope, so as to determine whether the quality of the ground active device array substrate 200 is acceptable. Since the line segments 241, 242, and 243 of the same lead 240 can be distinguished in vision, the worker can conveniently examine the active device array substrate 200 according to the appearances of the line segments 241, 242, and 243 after the grinding process, so as to accelerate the examination operation.

For example, when the active device array substrate 200 is ground, in a normal condition, that is, in a condition that the quality of the active device array substrate 200 is acceptable, the line segments 241 and the shorting rings 250a and 250b are completely removed, the line segments 242 are partially removed and partially retained on the substrate 210, and the line segments 243 are not ground but completely retained. In other words, after grinding, a normal active device array substrate 200 should retain a portion of the line segments 242 and the whole line segments 243.

However, in an abnormal condition, that is, in a condition that the quality of the active device array substrate 200 is unacceptable, it is possible that only the line segments 241 are partially removed. In this case, the active device array substrate 200 has to be reworked, so as to completely remove the line segments 241. Alternatively, it is also possible that the line segments 241, 242 are completely removed, the line segments 243 are partially removed or oven completely removed, and the terminals 230 are partially removed. In this case, the active device array substrate 200 may have to be reworked or even discarded.

In addition, in the LCD manufacturing process, the generation of electrostatic charges is unavoidable and causes an electrostatic discharge. Generally speaking, the electrostatic discharge easily occurs on a circuit with a small width. Once the electrostatic discharge occurs on the circuit, the circuit is damaged by the electrostatic charges, and it causes that the active device array substrate 200 is damaged, thereby reducing the yield.

As for two line segments connected to each other, a width of one line segment far away from the terminal 230 is smaller than a width of the other line segment, so that the electrostatic discharge easily occurs on the line segments 241 of the leads 240 as far as possible, and thus the line segments 241 are easily damaged by the electrostatic charges, so as to indirectly protect the line segments 242 and 243 and the terminals 230. Since the line segments 241 must be completely removed in the grinding process, the active device array substrate 200 is not easily damaged by the electrostatic charges even if the electrostatic charges damage the line segments 241.

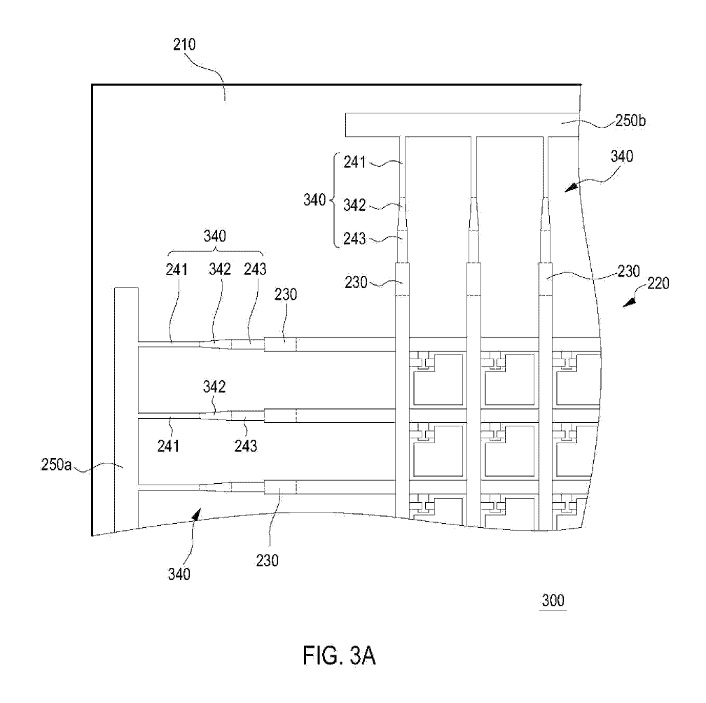

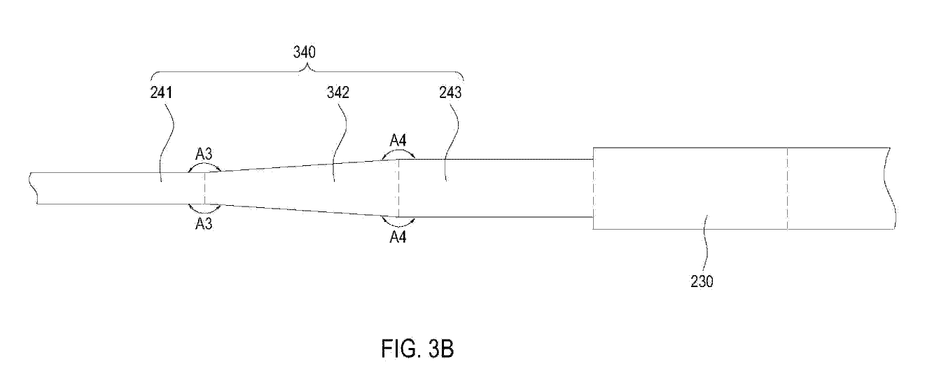

FIG. 3A is a schematic top view of an active device array substrate according to a second embodiment of the present invention, and FIG. 3B is a partially enlarged schematic view of a lead in FIG. 3A. Referring to FIGS. 3A and 3B, an active device array substrate 300 in the second embodiment includes a substrate 210, a pixel array 220, a plurality of terminals 230, a plurality of leads 340, and shorting rings 250a and 250b.

The structures and configuration relations of the substrate 210, the pixel array 220, the terminals 230, and the shorting rings 250a and 250b are the same as that of the first embodiment, so that the details will not be described herein again. In addition, the functions of the active device array substrate 300 and the manner for determining whether the quality of the ground active device array substrate 300 is acceptable are also the same as that in the first embodiment, so that the details will not be described herein again. However, the active device array substrate 300 according to this embodiment is different from that according to the first embodiment. The shapes of the leads 340 in this embodiment are different from the shapes of the leads 240 in the first embodiment.

The leads 340 are connected to the terminals 230, and each of leads 340 includes a plurality of line segments 241, 342, and 243. In the same lead 340, the line segments 241, 342, and 243 are connected to one another in series, and the line segment 342 is connected between the line segment 241 and the line segment 243. The line segments 241 and 243 are substantially rectangular, and the line segments 342 are substantially trapezoidal, as shown in FIG. 3B. It can be seen that two line segments have different shapes in the same lead 340.

In addition, in this embodiment, two angles A3 exist between the edge of the line segment 241 and the edge of the line segment 342 connected to the line segment 241. Two angles A4 exist between the edge of the line segment 342 and the edge of the line segment 243 connected to the line segment 342. The angles A3 are all smaller than 180°, and the angles A4 are all greater than 180°. In other words, the edges of the line segments 241 and 342 are not aligned with each other, and the edges of the line segments 243 and 342 are not aligned with each other, as shown in FIG. 3B. Therefore, the line segments 241, 342 and 243 of the same lead 340 can still be distinguished in vision, and it enables the worker to conveniently examine the active device array substrate 300, so as to accelerate the examination operation.

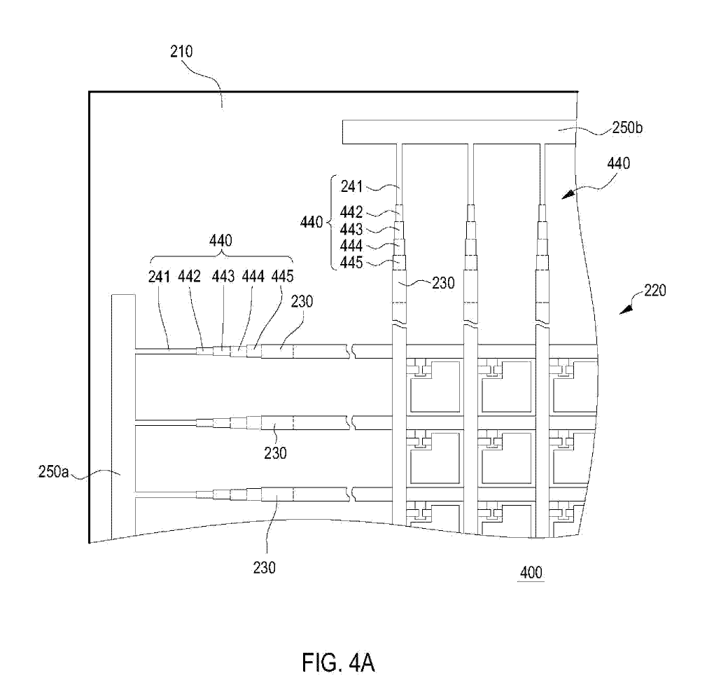

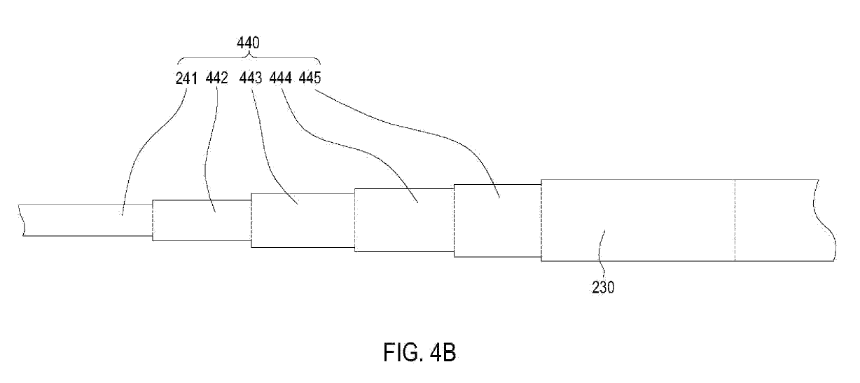

FIG. 4A is a schematic top view of an active device array substrate according to a third embodiment of the present invention, and FIG. 4B is a partially enlarged schematic view of a lead in FIG. 4A. Referring to FIGS. 4A and 4B, an active device array substrate 400 in the third embodiment includes a substrate 210, a pixel array 220, a plurality of terminals 230, a plurality of leads 440, and shorting rings 250a and 250b.

According to the above, the structures, functions, and configuration relations of the substrate 210, the pixel array 220, the terminals 230, and the shorting rings 250a and 250b are the same as that in the first embodiment, so that the details will not be described herein again. Hence, only the difference between this embodiment and the first embodiment is introduced below.

The overall shapes of the leads 440 in this embodiment are different from that of the leads 240 in the first embodiment. In detail, each lead 440 includes a plurality of line segments 241, 442, 443, 444, and 445. The line segments 241, 442, 443, 444, and 445 of the same lead 440 are connected to one another in series, and the number of line segments included by each lead 440 is five, which is more than three.

Since the number of line segments included by each lead 440 is more than three, the worker can not only determine whether the quality of the ground active device array substrate 400 is acceptable, but also monitor whether an abnormal event occurs to parameters of the grinding machine according to the appearances of the leads 440 after the active device array substrate 400 is ground.

For example, when the active device array substrate 400 is ground, in an optimum condition, that is, in a condition that the quality of the active device array substrate 400 is optimal, the line segments 241, 442, and the shorting rings 250a and 250b are completely removed, the line segments 443 are partially removed and partially retained on the substrate 210, and the line segments 444 and 445 are not ground but completely retained. In other words, after grinding, the optimal active device array substrate 400 should retain a portion of the line segments 443 and all of the line segments 444 and 445.

Moreover, when the quality of the active device array substrate 400 is still acceptable, but an abnormal event occurs to the parameters of the grinding machine, it is possible that the line segments 241 are completely removed, the line segments 442 are partially removed, and the line segments 443, 444, and 445 are completely retained. Alternatively, it is also possible that the line segments 241, 442, and 443 are completely removed, the line segments 444 are partially removed, and the line segments 445 are completely retained. It can be seen that, when the line segments 442 or the line segments 444 are partially removed, it indicates that an abnormal event occurs to the parameters of the grinding machine, and the grinding machine needs to be toned.

In an abnormal condition, that is, in a condition that the quality of the active device array substrate 400 is unacceptable, it is possible that only the line segments 241 are partially removed. In this case, the active device array substrate 400 may have to be reworked, so as to completely remove the line segments 241. Alternatively, it is also possible that the line segments 241, 442, 443 and 444 are completely removed, and the line segments 445 are partially removed, or even the line segments 445 are completely removed, and the terminals 230 are partially removed. In this case, the active device array substrate 400 may have to be reworked or even discarded.

Based on the above, since the plurality of line segments of the leads can be distinguished in vision, the worker can directly examine the leads under a common magnifying glass or optical microscope, so as to determine whether the quality of the ground active device array substrate is acceptable according to the appearances of the line segments after the grinding process. Thus, the present invention enables the worker to conveniently examine the active device array substrate, so as to accelerate the examination operation and reduce the time consumed by the examination operation.

In addition, different designs for the appearances of the leads may be provided in the present invention, and each lead is enabled to include more than three line segments. Thus, after the active device array substrate is ground, the worker can not only determine whether the quality of the ground active device array substrate is acceptable, but also monitor whether an abnormal event occurs to the parameters of the grinding machine according to the appearance of the leads after the grinding process, so as to determine in advance whether the grinding machine needs to be toned, thereby improving the yield.

Moreover, as for two line segments connected to each other, a width of one line segment far away from the terminal is smaller than that of the other line segment. Thus, the electrostatic discharge easily occurs to the line segments of the leads that must be completely removed in the grinding process, such that the other line segments retained and the terminals are indirectly protected, thereby reducing the probability of damaging the active device array substrate due to the electrostatic charge.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An active device array substrate, comprising:
a substrate;
a pixel array, disposed on the substrate, and comprising a plurality of intersecting signal lines arranged in a mesh shape;
a plurality of terminals, disposed on the substrate; and
a plurality of leads, disposed on the substrate, wherein each of the leads comprises a plurality of line segments connected in series, each of the terminals is connected between one of the line segments and one of the signal lines, two angles existing between an edge of one line segment and an edge of another line segment connected to the line segment, and the angles are not equal to 180°.

2. The active device array substrate according to claim 1, wherein in a same lead, a width of one line segment adjacent to the terminal is greater than a width of any other line segment.

3. The active device array substrate according to claim 2, wherein in two line segments connected to each other, a width of one line segment far away from the terminal is smaller than a width of an other line segment.

4. The active device array substrate according to claim 1, wherein two line segments of a same lead have different areas.

5. The active device array substrate according to claim 1, wherein two line segments of a same lead have different shapes.

6. The active device array substrate according to claim 1, wherein a lead comprises more than two line segments.

7. The active device array substrate according to claim 1, wherein a lead comprises more than three line segments.

8. The active device array substrate according to claim 1, wherein the angles are substantially equal to 90°.

9. The active device array substrate according to claim 1, wherein at least two angles are smaller than 180°.

10. The active device array substrate according to claim 1, wherein at least two angles are greater than 180°.

11. The active device array substrate according to claim 1, wherein the line segments are substantially rectangular.

12. The active device array substrate according to claim 1, wherein at least one line segment is substantially trapezoidal.

13. The active device array substrate according to claim 1, wherein some of the signal lines are a plurality of scan lines, and each of the scan lines is connected to one of the terminals.

14. The active device array substrate according to claim 1, wherein some of the signal lines are a plurality of data lines, and each of the data lines is connected to one of the terminals.

15. The active device array substrate according to claim 1, wherein the pixel array further comprises a plurality of pixel units, and the pixel units are electrically connected to the signal lines.
